(19) United States
(12) Patent Application Publication
(10) Pub. No.: US 2022/0345104 A1
(43) Pub. Date: Oct. 27, 2022

(54) Doubly Rotated Quartz Crystal Resonators With Reduced Sensitivity to Acceleration

(71) Applicants: David SALT, Walden Essex (GB); Ryan John BARRON, Auckland (NZ); Michael Shawn MICILROY, Auckland (NZ); RAKON LIMITED, Auckland (NZ)

(72) Inventors: David Salt, Saffron Walden Essex (GB); Ryan John Barron, Auckland (NZ); Michael Shawn McIlroy, Auckland (NZ)

(21) Appl. No.: 17/760,570

(22) PCT Filed: Sep. 16, 2020
(86) PCT No.: PCT/IB2020/058588

§ 371 Date: Mar. 15, 2022

(30) Foreign Application Priority Data
Sep. 16, 2019 (NZ) 757314

(51) Int. Cl. H03H 9/02; H03H 9/05; H03H 9/19

(52) U.S. Cl. CPC H03H 9/02133; H03H 9/0519; H03H 9/02551; H03H 9/19; H03H 2003/022

(57) ABSTRACT

A doubts rotated quart/crystal resonator comprises a cantilever-mounted doubts rotated resonating element having a line of geometrical symmetry running from a supported end to a free end which is not perpendicular to the resonating element's crystallographic/axis. A method of manufacturing the crystal resonator comprises cutting a doubly rotated quartz crystal plate with x^{I} and z^{I} axes defining the plate's plane into one or more resonating elements at a non-zero degrees in-plane rotation angle in relation to the plate's x^{I} axis. The resonator has reduced sensitivity to mechanical acceleration.

### FIELD OF THE INVENTION

The present invention relates to frequency control products used in a variety of applications where accurate and stable frequency reference and/or timing signals are required. More specifically, the present invention relates to doubly rotated quartz crystal resonators and crystal oscillator devices with reduced sensitivity to mechanical acceleration.

### BACKGROUND OF THE INVENTION

High frequency stability electronic oscillators are often built with quartz crystal resonators. The latter comprise a mounted piezo-electric resonating element and means of connecting the resonator to an electronic circuit to sustain stable vibration of the resonator.

The quartz crystal resonating element is typically made from a quartz plate (“quartz wafer”) that is produced by cutting up a piece of quartz material (“quartz bar”) at certain angles relative to the material's crystallographic axes. Various properties of the resonating element are dependent on the cut angles applied during the manufacture of the quartz plate. While there is an infinite number of ways the quartz plate can be cut in relation to the crystallographic axes x, y, and z, certain cuts have been identified that result in particularly useful properties of the resonator. FIG. 1 shows the orientation of widely used singly rotated cuts and doubly rotated cuts. A singly rotated cut plate 1 is obtained when the quartz plate is made by applying a rotation around the x axis from the z axis (the θ angle). Such a rotation defines new axes y^{I} and z^{I} for the singly rotated plate 1, whereas the plate's x^{I} axis remains parallel to the crystallographic axis x. A doubly rotated cut plate 2 is obtained when the quartz plate is made by applying double rotation: by the φ angle relative to the x axis around the z axis, and by the θ angle relative to the z axis around the x axis, thus defining new x^{I}, y^{I}, and z^{I} axes for the doubly rotated plate 2. The x^{I} axes in both the singly rotated plate 1 and the doubly rotated plate 2 remain perpendicular (i.e., at 90°) to the crystallographic axis z.

An example of a singly rotated cut is the commonly used AT cut, obtained when the quartz plate is made by applying a rotation around the x axis of approximately 35° (the θ angle) from the z axis. The AT cut exhibits properties that are useful for designing and manufacturing temperature compensated crystal oscillators. The stress compensated cut SC cut is an example of a doubly rotated cut, obtained when the quartz plate is made by applying double rotation: of approximately 22° (the φ angle) relative to the x axis around the z axis, thus defining a new x^{I} axis for the SC cut plate, and approximately 34° (the θ angle) relative to the z axis around the x axis. The SC cut quartz crystal resonator is said to be compensated for mechanical stresses applied along its in-plane axes. The IT cut is another example of a doubly rotated cut (φ≈19°, θ≈34°) that exhibits properties that are similar to those of the SC cut.

Individual quartz crystal resonating elements are manufactured by cutting (“dicing”) up quartz plates into individual “crystal blanks”; the resonating elements can be made of various shapes, with round and rectangular (“strip”) resonating elements being the commonly used ones.

A variety of resonating element mounting and packaging techniques are known. For example, as shown in FIG. 2 (prior art), a rectangular (“strip”) resonating element 6 can be mounted inside a resonator package 1 asymmetrically, using a cantilever mounting arrangement with one or more mounting points at one end of the resonating element 6 and with the second end of the resonating element being free; typically, the resonating element 6 is mounted to conductive pads 4 using one or two conductive glue dots 5, and the package is sealed off using a lid 3 and a seal ring 2.

FIG. 3 (prior art) shows a cross-sectional view of a rectangular resonating element 6 installed inside a resonator package 1 using a cantilever mounting arrangement comprising two mounting glue dots 5 at one end of the resonating element 6 and with the other end of the resonating element being free (i.e., unsupported). The resonating element's line of geometrical symmetry 7, running from the supported end of the resonating element 6 to its free end, can be defined.

FIG. 4 (prior art) shows a cross-sectional view of a rectangular resonating element 6 installed inside a resonator package 1 using a cantilever mounting arrangement with only one mounting glue dot 5 at one end of the resonating element 6 and with the other end of the resonating element being free (i.e., unsupported). The resonating element's line of geometrical symmetry 7, running from the supported end of the resonating element 6 to its free end, can be defined.

In prior art, individual resonating elements are manufactured by cutting up quartz plates in such a way that the aforementioned line of geometrical symmetry is parallel (i.e., at a zero degrees angle) to the x^{I} axis of the plate, which, as explained above, is positioned at an angle φ in relation to the crystallographic axis x and is perpendicular to the crystallographic axis z.

A well-recognized problem associated with quartz crystal resonators and oscillator devices utilizing quartz crystal resonators is their sensitivity to mechanical acceleration. It manifests itself as a change in the resonant frequency of the resonator, or a change in the frequency of the output signal of the crystal oscillator, caused by externally applied mechanical acceleration. Sensitivity of doubly rotated quartz crystal resonators to mechanical acceleration is often problematic in oven-controlled crystal oscillators (OCXO) and temperature-compensated crystal oscillators (TCXO) used in applications where significant mechanical acceleration is present.

Certain ways of reducing sensitivity to acceleration are known in prior art, such as those, for example, that are disclosed in U.S. Pat. Nos. 7,247,978 and 7,915,965.

It is an object of the present invention to provide new ways of reducing sensitivity to mechanical acceleration in cantilever-mounted doubly rotated crystal resonators.

### SUMMARY OF THE INVENTION

In one aspect, the invention may be said to comprise a method of manufacturing doubly rotated quartz crystal resonators comprising cantilever-mounted doubly rotated resonating elements, which method includes the step of applying an in-plane non-zero angle rotation around y^{I} axis and away from x^{I} axis when cutting up quartz plates into individual resonating elements.

In another aspect, the invention may be said to comprise a doubly rotated quartz crystal resonator comprising a cantilever-mounted doubly rotated resonating element wherein the line of geometrical symmetry running from the supported end of the cantilever-mounted resonating element to its free end is positioned at an angle relative to the crystallographic axis z that is different from 90°. In other words, in the cantilever-mounted doubly rotated resonating element of the invention the line of geometrical symmetry running from the supported end of the cantilever-mounted resonating element to its free end is not perpendicular to the crystallographic z axis of the quartz crystal material from which the resonating element is made. The said non-perpendicularity is due to the aforementioned non-zero angle in-plane rotation applied during manufacture of the resonating element.

In another aspect, the invention may be said to comprise a method of manufacturing doubly rotated SC cut quartz crystal resonators comprising cantilever-mounted resonating elements, which method includes the step of applying an in-plane rotation (around y^{I} axis, from x^{I} axis) within the azimuth angle range of 36° to 56° when cutting up quartz plates into individual resonating elements.

In another aspect, the invention may be said to comprise a doubly rotated SC cut quartz crystal resonator comprising a cantilever-mounted SC cut resonating element wherein the line of geometrical symmetry running from the supported end of the cantilever-mounted resonating element to its free end is positioned at an angle relative to the crystallographic axis z that is different from 90°. In other words, in the cantilever-mounted doubly rotated SC cut resonating element of the invention the line of geometrical symmetry running from the supported end of the cantilever-mounted resonating element to its free end is not perpendicular to the crystallographic z axis of the quartz crystal material from which the resonating element is made. The said non-perpendicularity is due to the aforementioned in-plane rotation around y^{I} axis from x^{I} axis within the azimuth angle range of 36° to 56° applied during manufacture of the resonating element.

In another aspect, the invention may be said to comprise a quartz crystal oscillator comprising a doubly rotated cantilever-mounted resonator according to the statements above.

In another aspect, the invention may be said to comprise an electronic device comprising a quartz crystal oscillator as per the statement above.

The term “comprising” as used in this specification means “consisting at least in part of”. When interpreting each statement in this specification that includes the term “comprising”, features other than that or those prefaced by the term may also be present. Related terms such as “comprise” and “comprises” are to be interpreted in the same manner.

### BRIEF DESCRIPTION OF THE DRAWINGS

The invention is further described with reference to the accompanying figures in which,

FIG. 1 shows the orientation of singly rotated and doubly rotated cuts (prior art).

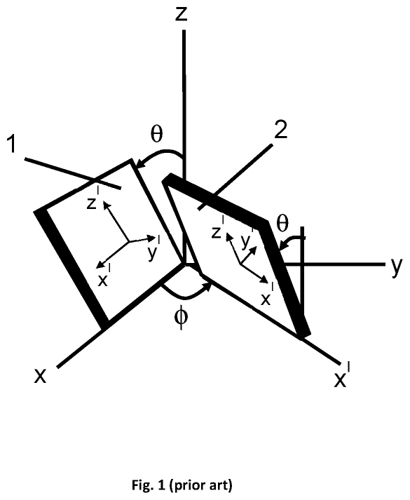

FIG. 2 is a schematic cross-section view of the structure of a cantilever-mounted strip crystal resonator (prior art).

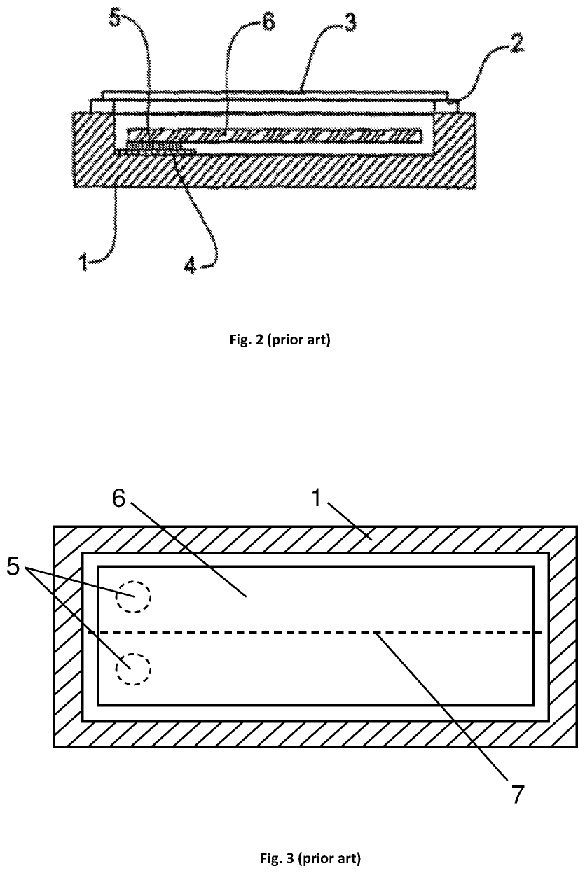

FIG. 3 is a schematic cross-section view of a two-point cantilever-mounted resonating element (prior art).

FIG. 4 is a schematic cross-section view of a single point cantilever-mounted resonating element (prior art).

FIG. 5 illustrates quartz wafer dicing as per prior art.

FIG. 6 illustrates wafer dicing as per the present invention.

FIG. 7 illustrates wafer dicing into multiple resonating elements with in-plane rotation as per the present invention.

FIG. 8 shows plots of directional and total acceleration sensitivity versus in-plane rotation angle for two-point cantilever-mounted SC cut resonator.

FIG. 9 shows plots of directional and total acceleration sensitivity versus in-plane rotation angle for single-point cantilever-mounted SC cut resonator.

FIGS. 10A, 10B, 10C, and 10D are plots of X, Y, Z, and total sensitivity to acceleration for a number of single point cantilever-mounted SC-cut strip resonators, further referred to in the subsequent experimental Example.

### DETAILED DESCRIPTION OF THE INVENTION

As stated, in accordance with the invention doubly rotated quartz crystal resonator elements are produced with a wafer dicing in-plane rotation.

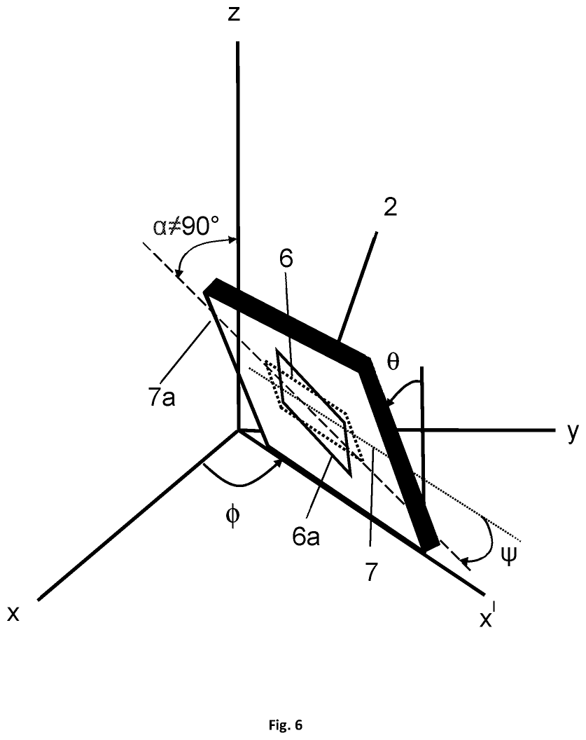

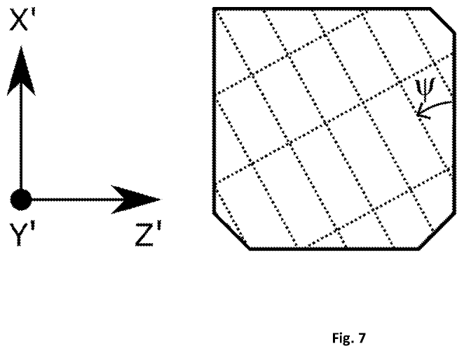

FIGS. 5 and 6 illustrate the concept of the invention. In FIG. 5 (prior art) a doubly rotated quartz wafer 2, cut at angles of φ and θ relative to the crystallographic axes x and z respectively, is cut to produce individual doubly rotated resonating elements. For illustration purposes, a single resonating element 6 is shown in FIG. 5; in practice, a number of resonating elements are produced from a quartz wafer. In prior art, the individual resonating elements are produced by dicing up the wafer in directions parallel and perpendicular to the x^{I} axis. The line of geometrical symmetry 7 of thus produced resonating elements is in parallel with the x^{I} axis of the wafer and therefore at 90° (shown as angle α) to the crystallographic z axis. In FIG. 6 a doubly rotated quartz wafer 2, cut at angles of φ and θ relative to the crystallographic axes x and z respectively, is used for making individual doubly rotated resonating elements as per the invention. Instead of producing the resonating elements by dicing up the wafer in directions parallel and perpendicular to the x^{I} axis of the wafer as is done in prior art (FIG. 5), the resonating elements of the present invention are produced (FIG. 6) by dicing up the wafer at a certain non-zero degrees angle Ψ (azimuth angle) of in-plane rotation in relation to the x^{I} axis. A resonating element 6 produced by methods of the prior art and its line of geometrical symmetry 7 are also shown in FIG. 6 to illustrate the in-plane rotation. The line of geometrical symmetry 7a of resonating element 6a produced as per the invention is not parallel to the x^{I} axis of the wafer and is not perpendicular to the crystallographic z axis, i.e. angle α≠90°. It can be shown that the exact value of the angle α between the line of geometrical symmetry 7a of resonating element 6a produced as per the invention and the crystallographic z axis is determined by the expression a α=90°−arcsin(cos θx sirΨ).

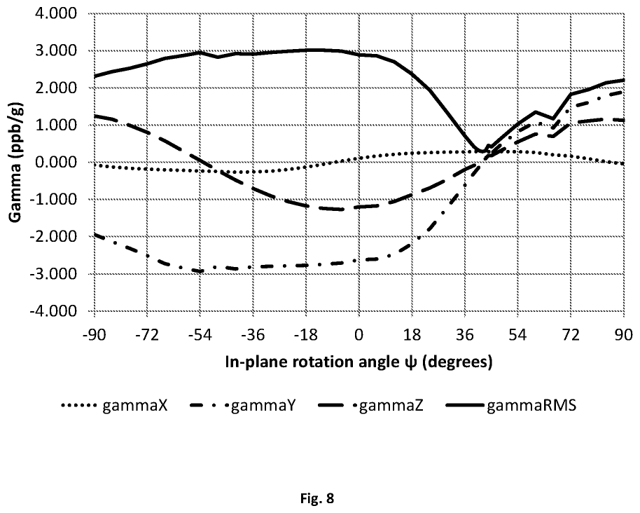

As stated, several resonating elements are usually produced from a single quartz wafer, as illustrated in FIG. 7 in which a quartz wafer and its x^{I}, y^{I}, and z^{I} axes are shown, along with the (dashed) lines of dicing that are in-plane rotated by a non-zero degrees angle Ψ in relation to the x^{I} axis as per the present invention.

Sensitivity to mechanical acceleration of a doubly rotated resonating element produced as per the present invention varies with, and depends on, the value of the in-plane rotation (azimuth) angle Ψ, and by selecting specific values of the azimuth angle the sensitivity to mechanical acceleration can be minimized or at least reduced. As explained further herein, the choice of a specific in-plane rotation angle Ψ value depends on factors such as the structure of cantilever mounting of the resonating element and the extent of acceleration sensitivity reduction to be achieved.

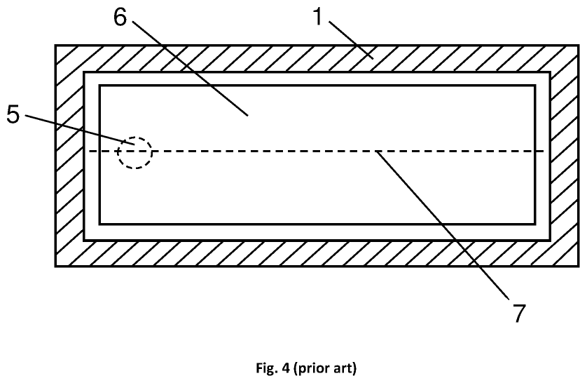

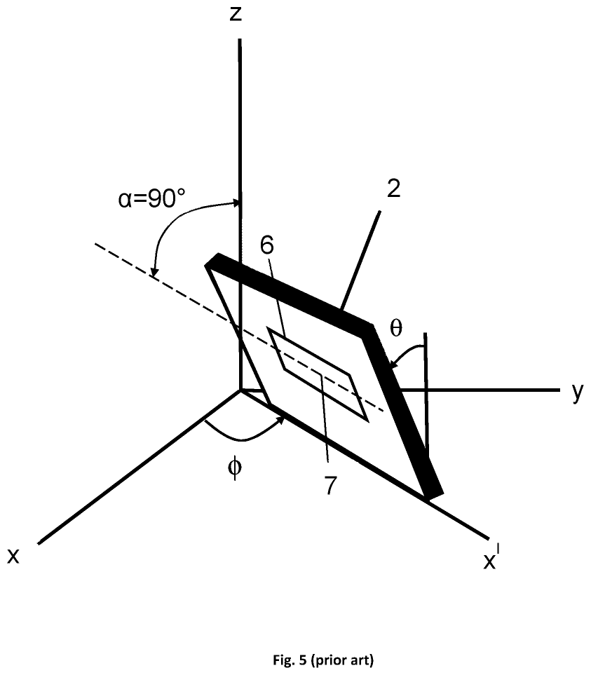

As with resonating elements of prior art (FIGS. 3 and 4), doubly rotated resonating elements of the present invention can also be cantilever-mounted, either on two mounting points or on one mounting point located at one end of the resonating element, with the other end of the resonating element being free.

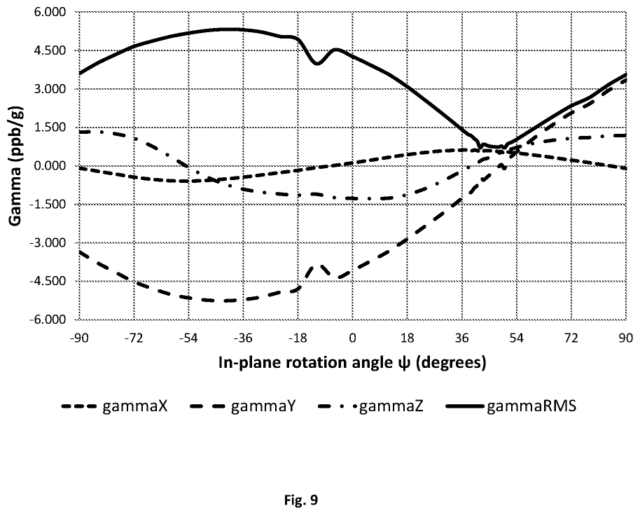

Sensitivity to mechanical acceleration exhibited by doubly rotated, two-point cantilever-mounted SC cut resonating elements of the invention varies with in-plane rotation angle as shown in FIG. 8, in which acceleration sensitivity in each of three mutually perpendicular directions X, Y, and Z (gammaX, gammaY, and gammaZ) as well as the total acceleration sensitivity (gammaRMS) are plotted as functions of the in-plane rotation angle Ψ. Acceleration sensitivity values are measured in parts-per-billion of frequency change per acceleration unit (ppb/g), whereas the angle Ψ values are measured in angular degrees.

As shown in FIG. 8, the total acceleration sensitivity “gammaRMS” (a root mean square value of directional acceleration sensitivity values “gammaX”, “gammaY”, and “gammaZ” in three mutually perpendicular directions) is around its minimal value when an in-plane rotation of 36°≤Ψ≤56° is applied to produce the resonating elements from a doubly rotated SC cut quartz wafer. Compared to two-point cantilever mounted SC cut resonators produced without the in-plane rotation (i.e., zero rotation angle in FIG. 8) that exhibit a total acceleration sensitivity of about 3 ppb/g, similarly mounted SC cut resonators produced with the in-plane rotation of 36°≤Ψ≤56° exhibit a total acceleration sensitivity below 1 ppb/g.

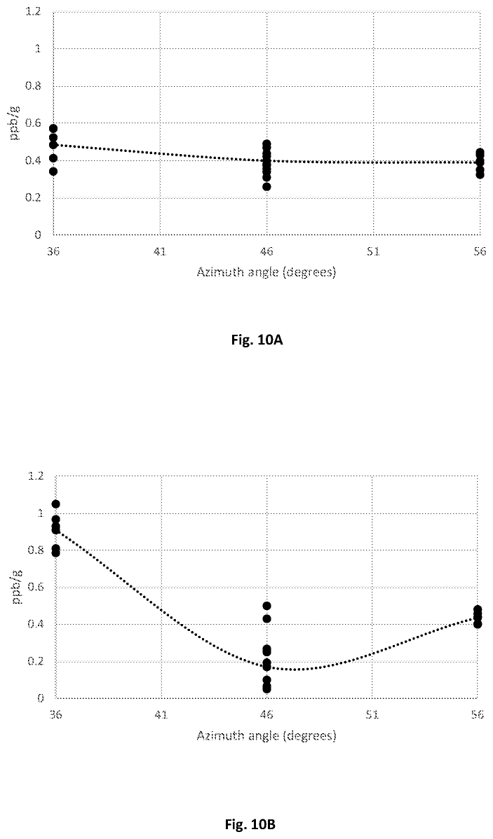

Sensitivity to mechanical acceleration exhibited by doubly rotated, single-point cantilever-mounted SC cut resonating elements of the invention varies with in-plane rotation angle as shown in FIG. 9, in which acceleration sensitivity in each of three mutually perpendicular directions X, Y, and Z (gammaX, gammaY, and gammaZ) as well as the total acceleration sensitivity (gammaRMS) are plotted as functions of the in-plane rotation angle Ψ. Acceleration sensitivity values are measured in parts-per-billion of frequency change per acceleration unit (ppb/g), whereas the angle Ψ values are measured in angular degrees.

As shown in FIG. 9, the total acceleration sensitivity “gammaRMS” (a root mean square value of directional acceleration sensitivity values “gammaX”, “gammaY”, and “gammaZ” in three mutually perpendicular directions) is around its minimal value when an in-plane rotation of 36≤Ψ≤56° is applied to produce the resonating elements from a doubly rotated SC cut quartz wafer. Compared to single-point cantilever mounted SC cut resonators produced without the in-plane rotation (i.e., zero rotation angle in FIG. 9) that exhibit a total acceleration sensitivity of about 4.5 ppb/g, similarly mounted SC cut resonators produced with the in-plane rotation of 36≤Ψ23 56° exhibit a total acceleration sensitivity below 2 ppb/g.

As has already been stated, in doubly rotated resonating elements of the present invention the line of geometrical symmetry is not perpendicular to the crystallographic z axis (angle α≠90°) and that the exact value of the angle α between the line of geometrical symmetry of resonating elements produced as per the invention and the crystallographic z axis is determined by the aforementioned expression. It follows from that expression that for doubly rotated resonating elements with θ=34°±20′ (such as, for example, the SC cut and IT cut resonating elements) and the in-plane rotation angle of 36°≤Ψ≤56°, the angle α will be within the range from 46° to 61°.

It should be noted that the sign of the azimuth angle (for example, positive +46° or negative −46°) depends in practice on the convention adopted within the manufacturing process implemented at a specific manufacturer: i.e., some manufacturers will consider a clockwise in-plane rotation to be “positive”, others may call an anticlockwise in-plane rotation “positive”. As follows from FIGS. 8 and 9, in-plane rotation in only one of directions will result in reduced sensitivity to acceleration. The important point for any embodiment of the present invention is the selection of the suitable absolute value of the azimuth angle.

### EXAMPLE

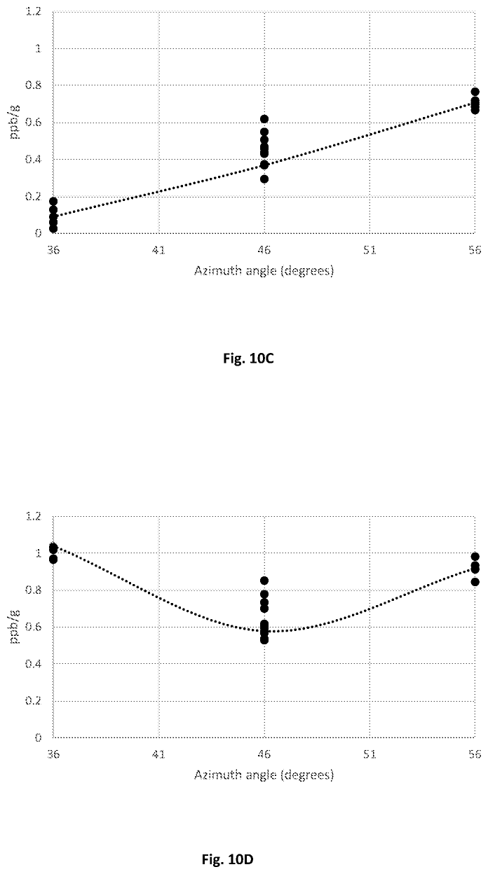

A number of single-point cantilever-mounted SC-cut (θ=33°45′, φ=21°56′) strip resonators of size 5.0 mm×3.2 mm and nominal resonant frequency of 19.2 MHz were produced with in-plane rotation (azimuth) angle Ψ of 36°, 46°, and 56°, and their sensitivity to acceleration was measured in three mutually perpendicular directions X, Y, and Z, with the total sensitivity determined based on the measurement results. The results are plotted in FIGS. 10A-10D, in which FIG. 10A plots X axis acceleration sensitivity magnitude values, FIG. 10B plots Y axis acceleration sensitivity magnitude values, FIG. 10C plots Z axis acceleration sensitivity magnitude values, and FIG. 10D plots the total acceleration sensitivity magnitude values for each of the three in-plane rotation angles (36°, 46°, and 56°). In these figures each data point represents a result for one resonator at that in-plane rotation angle value, and the dotted lines plot an estimated relationship through an average of the data points at each angle. It follows from the experimental data presented in FIG. 10A-10D that in-plane rotation of 36° to 56° applied when producing single point cantilever mounted SC cut resonators allows to achieve a reduction in the resonators' total acceleration sensitivity to levels below 1 ppb/g.

Thus, by applying a specific in-plane rotation during the wafer dicing in manufacture of doubly rotated quartz crystal resonating elements, sensitivity to mechanical acceleration of cantilever-mounted strip resonators can be substantially reduced.

The choice of a specific value of the in-plane rotation angle for doubly rotated quartz crystal resonator manufacture depends on the resonator design goals. For example, if an SC cut single-point cantilever-mounted resonator design is aimed at achieving the minimal total sensitivity to acceleration, then, as shown in FIG. 10D, an in-plane rotation angle value in close vicinity of 46° should be selected for the manufacture of the resonating elements of the present invention. If, on the other hand, the resonator is intended for an application where reduced sensitivity to acceleration in direction Z is particularly important, then a lower in-plane rotation angle, perhaps within the range from 36° to 46° (refer to FIG. 10C), will be selected for manufacture, which would result in even lower acceleration sensitivity in Z direction, although at the expense of a slight increase in the total acceleration sensitivity value.

Cantilever-mounted doubly rotated quartz crystal resonators of the present invention can be used in a variety of frequency control products, including, but not limited to, crystal oscillators (XO), temperature-compensated crystal oscillators (TCXO), and oven-controlled crystal oscillators (OCXO). These devices, in turn, will benefit the performance of various electronic devices and systems, including, but not limited to, radio communication devices, where reduced sensitivity of the reference frequency to mechanical acceleration is important.

1.-12. (canceled)

13. A method of manufacturing of a doubly rotated quartz crystal resonator with reduced sensitivity to mechanical acceleration comprising a cantilever-mounted doubly rotated resonating element, which method comprises the step of cutting a doubly rotated quartz crystal plate with x^{I} and z^{I} axes defining the plate's x^{I}z^{I} plane into one or more resonating elements at an in-plane rotation angle in relation to the plate's x^{I} axis in the range from about 36° to about 56°.

14. A method according to claim 13, wherein the doubly rotated quartz crystal resonator is a stress-compensated (SC) cut quartz crystal resonator, the cantilever-mounted doubly rotated resonating element is a cantilever-mounted SC cut resonating element, and the doubly rotated quartz crystal plate is an SC cut quartz crystal plate.

15. A doubly rotated quartz crystal resonator with reduced sensitivity to mechanical acceleration comprising a cantilever-mounted doubly rotated resonating element having a line of geometrical symmetry running from a supported end to a free end of the cantilever-mounted resonating element wherein an angle between the line of the resonating element's geometrical symmetry and the crystallographic z axis is in the range from about 46° to about 61°.

16. A quartz crystal resonator with reduced sensitivity to mechanical acceleration according to claim 15, wherein the cantilever-mounted doubly rotated resonating element is a two-point cantilever-mounted doubly rotated resonating element.

17. A quartz crystal resonator with reduced sensitivity to mechanical acceleration according to claim 15, wherein the cantilever-mounted doubly rotated resonating element is a single-point cantilever-mounted doubly rotated resonating element.

18. A quartz crystal resonator with reduced sensitivity to mechanical acceleration according to claim 15 that exhibits total acceleration sensitivity of an absolute value below 2 ppb/g.

19. A quartz crystal resonator with reduced sensitivity to mechanical acceleration according to claim 15 that exhibits total acceleration sensitivity of an absolute value below 1 ppb/g .

20. A doubly rotated quartz crystal resonator according to claim 15, wherein the said resonator is a stress-compensated (SC) cut quartz crystal resonator and the cantilever-mounted doubly rotated resonating element is a cantilever-mounted doubly rotated SC cut resonating element.

21. A quartz crystal oscillator comprising a resonator according to claim 15.

22. An electronic device comprising a quartz crystal oscillator according to claim 21.

23. A method of manufacturing of a doubly rotated resonating element suitable to construct a doubly rotated quartz crystal resonator with reduced sensitivity to mechanical acceleration, which method comprises the step of cutting a doubly rotated quartz crystal plate with x^{I} and z^{I} axes defining the plate's x^{I}z^{I} plane into one or more resonating elements at an in-plane rotation angle in relation to the plate's x^{I} axis in the range from about 36° to about 56°.

24. A method according to claim 23, wherein the doubly rotated quartz crystal resonator is a stress-compensated (SC) cut quartz crystal resonator, the doubly rotated resonating element is an SC cut resonating element, and the doubly rotated quartz crystal plate is an SC cut quartz crystal plate.

25. A doubly rotated resonating element suitable to construct a doubly rotated quartz crystal resonator with reduced sensitivity to mechanical acceleration wherein an angle between a line of the resonating element's geometrical symmetry and the crystallographic z axis is in the range from about 46° to about 61°.

26. A doubly rotated resonating element according to claim 25, wherein the said doubly rotated quartz crystal resonator is a stress-compensated (SC) cut quartz crystal resonator and the doubly rotated resonating element is an SC cut resonating element.
